(19) United States
(12) Patent Application Publication
(10) Pub. No.: US 2004/0021526 A1
(43) Pub. Date: Feb. 5, 2004

(54) Wideband 180° bit phase shifter

(75) Inventors: Myung-Deuk Jeong, Daejeon (KR); Joong-Soo Lim, Daejeon (KR); Joon-Ho So, Daejeon (KR); Hyun-Ik Shin, Daejeon (KR)

Correspondence Address: Leopold Presser, Scully, Scott, Murphy & Presser, 400 Garden City Plaza, Garden City, NY, 11530, US

(73) Assignee: AGENCY FOR DEFENSE DEVELOPMENT, DAEJEON (KR)

(21) Appl. No.: 10/617,921

(22) Filed: Jul. 11, 2003

(30) Foreign Application Priority Data
Jul. 30, 2002 (KR) 45076/2002

(51) Int. Cl. H03H 7/38

(52) U.S. Cl. 333/32

(57) ABSTRACT

A wideband 180° bit phase shifter has a simplified circuit construction by using a grounded switching device. The wideband 180° bit phase shifter includes a Lange coupler having an input port, an output port, a through port and a coupled port; and reflective loads respectively connected to the through port and the coupled port of the Lange coupler in order to reflect inputted radio signals.

### BACKGROUND OF THE INVENTION

1. Field of the Invention

The present invention relates to a wideband 180° bit phase shifter, and in particular to a wideband 180°. phase shifter having a simplified circuit construction by using a grounded switching device.

2. Description of the Prior Art

FIG. 1 is a block diagram illustrating a conventional 180° bit phase shifter. The 180° bit phase shifter includes an input switch 1, an output switch 4, a shorted π-type circuit 2 and a shorted Lange coupler 3. The phase shifter receives a radio frequency signal (hereinafter, it is referred to a “RF” signal) and outputs two signals having a phase difference of 180° with each other by operation of the switch.

Reference numeral 10 is a circuit diagram of the input switch 1, and the output switch 4 has the same construction as that of the input switch 1. As depicted in FIG. 1, each switch 1, 4 have a very complicated construction including at least four PIN diodes. Accordingly, the conventional phase shifter requires a wide area since it includes a plurality of devices.

### SUMMARY OF THE INVENTION

In order to solve the above-mentioned problem, it is an object of the present invention to provide a wideband 180° bit phase shifter having a simplified construction in comparison with the conventional phase shifter.

It is another object of the present invention to provide a wideband 180° bit phase shifter capable of decreasing an installation area in fabrication of a planar type phase shifter such as a MMIC (monolithic microwave integrated circuits) and a HMIC (hybrid microwave integrated circuits), etc.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

In the drawings:

FIG. 1 is a block diagram illustrating the conventional 180° bit phase shifter;

FIG. 2 is a block diagram illustrating a wideband 180° bit phase shifter in accordance with the present invention;

FIG. 3 is a circuit diagram illustrating the wideband 180° bit phase shifter in accordance with the present invention; and

FIG. 4 is a graph showing outputs of the wideband 180° bit phase shifter in accordance with the present invention.

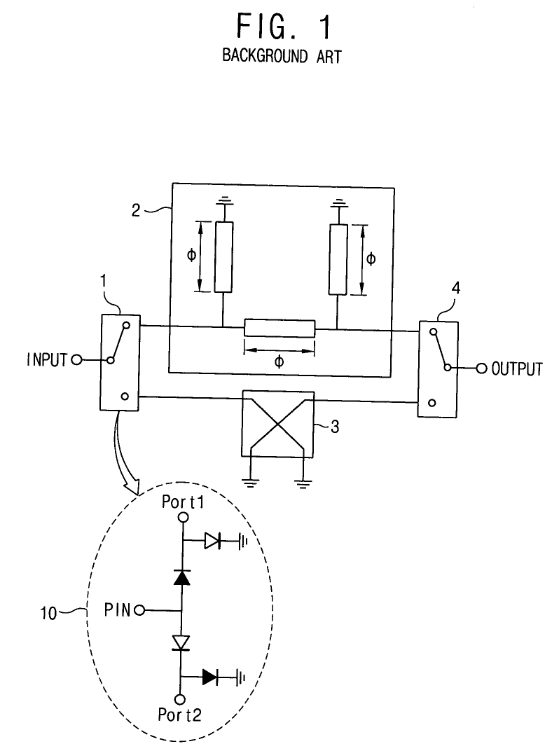

### DETAILED DESCRIPTION OF THE PREFERRED EMBODIMENT

A wideband 180° bit phase shifter in accordance with the present invention includes a Lange coupler having an input port, an output port, a through port and a coupled port; and reflective loads respectively connected to the through port and the coupled port of the Lange coupler in order to reflect inputted radio signals.

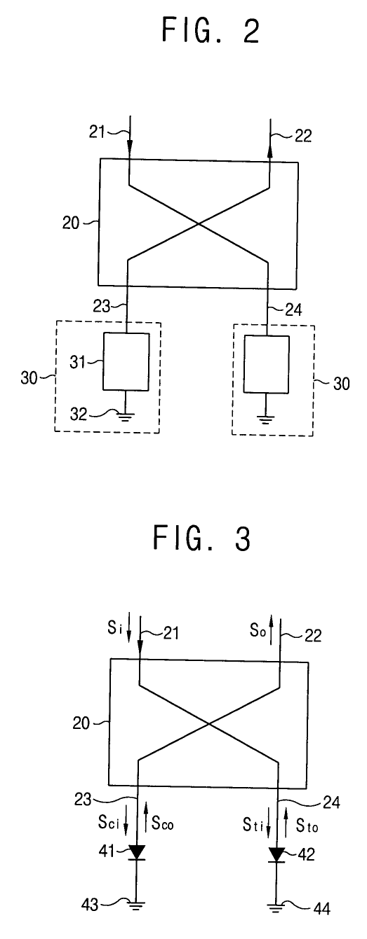

FIG. 2 is a block diagram illustrating a wideband 180° bit phase shifter in accordance with the present invention. It includes a Lange coupler 20; and two reflective loads 30 for reflecting signals received from the Lange coupler 20.

In more detail, the Lange coupler 20 includes an input port 21, an isolated port or an output port 22, a coupled port 23 and a through port 24. The reflective loads 30 respectively include a switching device 31 and a ground 32. And, the reflective loads 30 are respectively connected to the coupled port 23 and the through port 24.

FIG. 3 is a circuit diagram illustrating the wideband 180° bit phase shifter in accordance with the present invention. As depicted in FIG. 3, each PIN diode 41, 42 can be used as the switching device 31, and each ground 43, 44 can be formed as a via hole. The PIN diodes 41, 42 are simultaneously turned on/off by a certain control circuit (not shown). An equivalent circuit of the PIN diode can be approximated as about 1.5 Ω resistance in turning on of the diode, while it can be approximated as about 50 fF capacitor in turning off of the diode.

Hereinafter, the operation of the wideband 180° bit phase shifter in accordance with the present invention will be described. First, when a RF signal (Si) of P∠0° (herein, P is a size of a received signal) is received through the input port 21, a RF signal (Sci) of ½ PZ∠0° is inputted from the coupled port 23 to the PIN diode 41, and a RF signal (Sti) of ½ PZ∠90° is inputted from the through port 24 to the PIN diode 42.

First, when both the PIN diodes 41, 42 are open, that is, both the PIN diodes 41, 42 are turned off, a reflection coefficient of the reflective load 30 is almost 1. Therefore, a RF signal (Sco) of ½ PZφ0° is reflected to the coupled port 23, and a RF signal (Sto) of ½ PZ∠90° is reflected to the through port 24. The reflected RF signals are inputted again to the Lange coupler 20. In the input port 21, as the RF signals (Sco, Sto) pass, through the Lange coupler 20, the RF signal of ½ P∠0° and the RF signal of ½ P∠180° (that is, the RF signals having a phase difference of 180° with each other) are added. Accordingly, the input port 21 outputs a RF signal of 0 by offsetting the RF signals. On the other hand, in the output port 22, as the RF signals (Sco, Sto) pass through the Lange coupler 20, two RF signals of ½ P∠90° are added. Accordingly, the output port 22 outputs a RF signal of P∠90°.

Second, when both the PIN diodes 41, 42 are shorted, that is, both the PIN diodes 41, 42 are turned on, a reflection coefficient of the reflective load 30 is almost −1. Therefore, a RF signal (Sco) of ½ P∠−180° is reflected to the coupled port 23, and a RF signal (Sto) of ½ P∠−90° is reflected to the through port 24. The reflected RF signals are inputted again to the Lange coupler 20. In the input port 21, as the RF signals (Sco, Sto) pass through the Lange coupler 20, the RF signal of ½ P∠−180° and the RF signal of ½ P∠0° (that is, the RF signals having a phase difference of 180° with each other) are added. Accordingly, the input port 21 outputs a RF signal of 0 by offsetting the RF signals. On the other hand, in the output port 22, as the RF signals (Sco, Sto) pass through the Lange coupler 20, two RF signals of ½ P∠−90° are added. Accordingly, the output port 22 outputs a RF signal of P∠−90°.

The RF signal of P∠90° and the RF signal of P∠−90° are outputted to the output port 22, and accordingly RF signals having a phase difference of 180° with each other are generated.

Besides the PIN diodes 41, 42, a MESFET and a HEMT, etc. can be used as the switch 31.

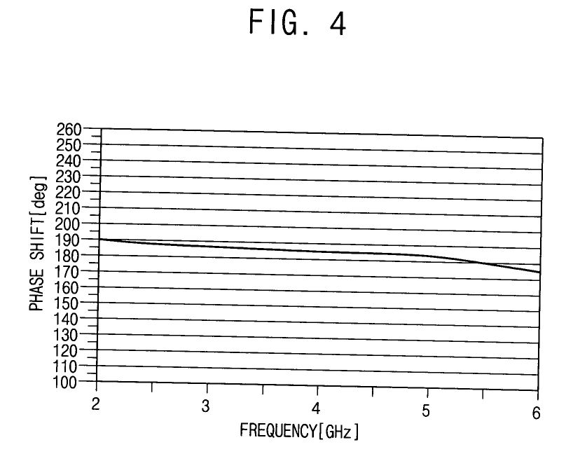

FIG. 4 is a graph showing outputs of the wideband 180° bit phase shifter in accordance with the present invention. Results in the range of 2 GHz˜6 GHz are shown. It is noted that a phase shift of almost 180° occurs in a frequency band range of 2 GHz˜6 GHz.

In the present invention, although the construction of the phase shifter is greatly simplified, it is possible to obtain a phase shift of 180°.

In addition, in the present invention, by decreasing an area of a phase shifter on a wafer greatly, yield rate of the wafer can be increased.

What is claimed is:

1. A wideband 180° bit phase shifter, comprising:
a Lange coupler having an input port, an output port, a through port and a coupled port; and
reflective loads respectively connected to the through port and the coupled port of the Lange coupler in order to reflect inputted radio signals.

2. The wideband 180° bit phase shifter of claim 1, wherein each reflective load includes a switching device in which one side thereof is grounded.

3. The wideband 180° bit phase shifter of claim 2, wherein the switching device is a PIN diode.

4. The wideband 180° bit phase shifter of claim 2, wherein the ground is a via hole.
